(19) United States
(12) Patent Application Publication
(10) Pub. No.: US 2026/0040735 A1
(43) Pub. Date: Feb. 5, 2026

(54) BULK InGaN COLOR CONVERSION FOR INTEGRATED CIRCUIT LIGHT SOURCES

(71) Applicant: Tectus Corporation, Cupertino, CA (US)

(72) Inventor: Paul Scott Martin, Palo Alto, CA (US)

(21) Appl. No.: 19/282,876

(22) Filed: Jul. 28, 2025

Related U.S. Application Data
(60) Provisional application No. 63/677,093, filed on Jul. 30, 2024.

(51) Int. Cl. H10H 20/851; H01L 25/075; H01L 25/16; H10H 20/01; H10H 20/814; H10H 20/825; H10H 29/14; H10H 29/45

(52) U.S. Cl. CPC H10H 20/8512; H01L 25/0753; H01L 25/167; H10H 20/0137; H10H 20/814; H10H 20/825; H10H 29/142; H10H 29/45

(57) ABSTRACT

An LED source includes a CMOS layer, a GaN LED layer, and a bulk InₓGa₁₋ₓN color conversion layer. The CMOS layer contains CMOS driver circuits. The GaN LED layer is attached to the CMOS layer. It is patterned into an array of LEDs connected to and driven by the driver circuits. The bulk InₓGa₁₋ₓN color conversion layer is attached to the GaN LED layer. The bulk InₓGa₁₋ₓN color conversion layer is patterned into color conversion elements aligned with corresponding LEDs to convert light from the LEDs to a different wavelength.

### CROSS-REFERENCE TO RELATED APPLICATION(S)

This application claims priority under 35 U.S.C. § 119 (e) to U.S. Provisional Patent Application Ser. No. 63/677,093, “Bulk InGaN color conversion for micro-LED displays,” filed Jul. 30, 2024. The subject matter of all of the foregoing is incorporated herein by reference in its entirety.

### BACKGROUND

### 1. Technical Field

This disclosure relates generally to color conversion for light sources.

### 2. Description of Related Art

Large arrays of small, efficient light sources are in high demand for a variety of applications, including color displays in augmented reality/virtual reality googles, phones and watches, notebook computers and tablets, televisions and monitors, automobile displays and large area displays. Arrays of blue micro-light-emitting-diodes (micro-LEDs) are promising candidates for these applications. Light emitted from a subset of the blue micro-LEDs in an array may be converted to red or green using a variety of color conversion techniques.

### BRIEF DESCRIPTION OF THE DRAWINGS

Embodiments of the disclosure have other advantages and features which will be more readily apparent from the following detailed description and the appended claims, when taken in conjunction with the examples in the accompanying drawings, in which:

FIG. 1 shows a light emitter using bulk InGaN for color conversion.

FIG. 2 shows another light emitter using bulk InGaN for color conversion, with a distributed Bragg reflector (DBR).

FIG. 3A shows a micro-LED array with a continuous bulk layer of InₓGa₁₋ₓN.

FIG. 3B shows a micro-LED array with a patterned bulk layer of InₓGa₁₋ₓN.

FIGS. 4A-4E shows fabrication of a micro-LED array with a bulk InGaN color conversion layer.

FIG. 5 is a flow chart for a method of making a micro-LED display with a bulk InGaN color conversion layer.

### DETAILED DESCRIPTION OF THE PREFERRED EMBODIMENTS

The figures and the following description relate to preferred embodiments by way of illustration only. It should be noted that from the following discussion, alternative embodiments of the structures and methods disclosed herein will be readily recognized as viable alternatives that may be employed without departing from the principles of what is claimed.

Aspects of the present disclosure relate to bulk InGaN color conversion for integrated circuit light sources. Micro-LEDs can be efficient and bright. Pixels in a micro-LED light source may therefore be made very small to provide high spatial resolution, to produce as many pixels as possible from an LED wafer, or both. Here “small” pixels may be less than about 2 μm in width. LEDs for small pixels may be tall and narrow, with a height/width aspect ratio greater than one.

One way to produce different colors is to employ selective area growth to create different color LEDs at different places on a wafer. However, red micro-LEDs may have significantly worse performance than blue micro-LEDs, and selective area growth is difficult at pixel sizes less than about 10 μm.

An alternate approach is to use quantum dots to convert blue light to red or green light for subsets of the LEDs. However, quantum dots have low optical absorption per unit path length. As a result, color conversion requires some path length. When the path length is comparable to, or greater than, the pixel width, then the height/width aspect ratio of the quantum dot color converter may be greater than one. It may become impractical to make color converters as the aspect ratio increases beyond approximately three and light extraction efficiency is also reduced as aspect ratio increases.

On the other hand, color conversion in three-dimensional structures, such as bulk films, can be accomplished in shorter optical path lengths because the greater density of states leads to more absorption. For example, bulk InₓGa₁₋ₓN, with 0≤x≤1, preferably 0<x<1 or even 0.1<x<0.5, may be used for color conversion. It may be deposited on GaN micro-LEDs as a color converting layer. In bulk materials, the relevant properties of the material are the same as the properties of a large chunk of that material without regard for surfaces or interfaces. As a counterexample, quantum wells and quantum dots are not bulk materials. Bulk InₓGa₁₋ₓN features a high density of states and therefore high absorption. As a result, the color conversion element can utilize a short path length, which results in a lower aspect ratio and better optical performance.

InₓGa₁₋ₓN may be grown via metal-organic chemical vapor deposition (MOCVD) at 700 to 800 degrees Celsius. However, deposition at that temperature is incompatible with CMOS wafers and thus prevents integration of MOCVD bulk InₓGa₁₋ₓN films with arrays of GaN micro-LEDs that have already been integrated with a CMOS wafer.

A solution to this problem is to use low-temperature (e.g. less than about 300 degrees Celsius) processes like atomic layer deposition (ALD) or radio frequency (RF) sputtering to deposit bulk InₓGa₁₋ₓN films without damaging the CMOS circuitry. After low-temperature deposition, a bulk InₓGa₁₋ₓN film may be patterned in a CMOS fab using standard lithography techniques.

Optionally, a wavelength-selective distributed Bragg reflector (DBR) may subsequently be formed on the bulk InₓGa₁₋ₓN color converting layer to make resonant cavity LEDs and narrow the radiation pattern in the forward direction.

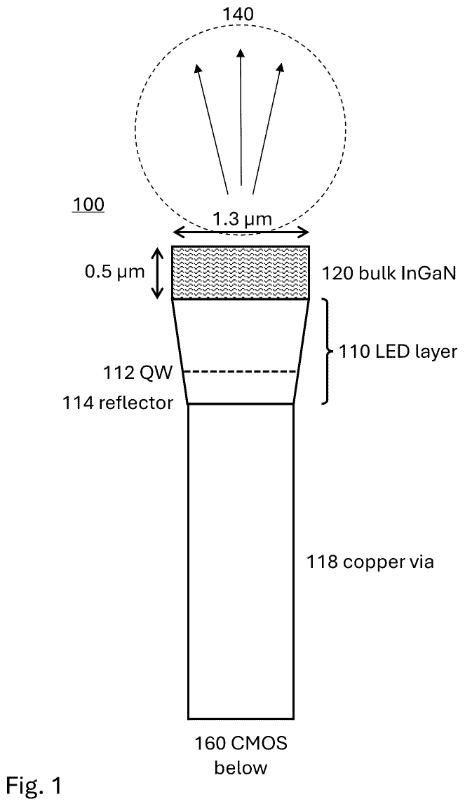

Turning now to the drawings, FIG. 1 shows a single light emitter 100 using a GaN LED 110 as the light source and bulk InₓGa₁₋ₓN 120 as the color conversion element. The color conversion element 120 is formed on an LED 110, which in this example includes a quantum well (QW) 112 (or multiple quantum wells) active region between n- and p-layers. The LED also includes a reflector 114. The LED 110 is patterned in an LED wafer that is hybrid bonded (by copper vias 118) to a CMOS Si wafer 160 (not shown in FIG. 1).

Before the LED wafer is bonded to the CMOS wafer, LEDs 110 are made by growing bulk GaN and GaN quantum wells on a substrate like Si or Al₂O₃. That substrate and the GaN LED layer are then bonded to the CMOS wafer by copper vias 118, in a hybrid bonding or “direct bond interconnect” (DBI) process. The substrate is then removed, and the remaining GaN is thinned, leaving the LED layer 110 shown in the figure. The color converter 120 is formed on top of LEDs 110 patterned in the LED layer.

In the example of FIG. 1, the height/width aspect ratio of the bulk InₓGa₁₋ₓN color converter 120 is less than one, about 0.4 (0.5 μm/1.3 μm) in this example. The low aspect ratio is possible because the high density of states of bulk InₓGa₁₋ₓN allows the InₓGa₁₋ₓN layer to be thinner for a given amount of absorption required. That in turn means that LEDs 110 may be smaller for a given minimum InₓGa₁₋ₓN layer thickness without the color converting element 120 needing a high aspect ratio which may be difficult or impractical to fabricate. High bulk density of states and high absorption enable small LED size and low color converter aspect ratio. This enables full color micro-LED displays or other applications with pixels smaller than two microns, for example. In one application, bulk InₓGa₁₋ₓN absorption was six times higher per unit path length than that of quantum dots.

The dashed circle 140 in FIG. 1 is the radiation pattern emitted by the light emitter 100. The pattern has a wide emission angle and may approach a Lambertian pattern.

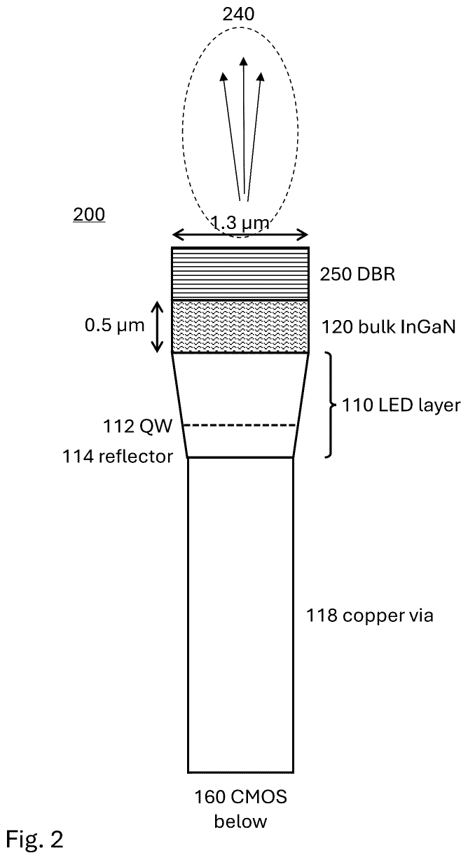

FIG. 2 shows a single light emitter 200 similar to the one shown in FIG. 1, with an added distributed Bragg reflector (DBR) 250. The DBR 250 makes the LED 110 into a resonant cavity LED, where the two end mirrors of the resonant cavity are the bottom reflector 114 and the DBR 250. This promotes more complete color conversion by the bulk InₓGa₁₋ₓN 120 and narrows the radiation pattern 240 in the forward direction.

Bulk InₓGa₁₋ₓN color conversion elements may be made by depositing and patterning bulk InₓGa₁₋ₓN on micro-LEDs in a low temperature process. The process may be repeated to deposit Inₓ₁Ga₁₋ₓ₁N and Inₓ₂Ga₁₋ₓ₂N (x1≠x2) on separate subsets of LEDs in an array for conversion to different colors. LEDs with Inₓ₁Ga₁₋ₓ₁N, Inₓ₂Ga₁₋ₓ₂N (x2≠x1), or no color conversion element, may then form red, green and blue light emitters, respectively.

These may be organized into individually addressable color pixels for a color display. Different organizations of LEDs and color conversion elements are possible depending on the application. For example, light from all (or less than all) of the LEDs may be converted to different wavelengths. The light could be converted to multiple different wavelengths using different types of color conversion elements. A color conversion element could receive light from multiple LEDs, or even other light sources such as VCSELs.

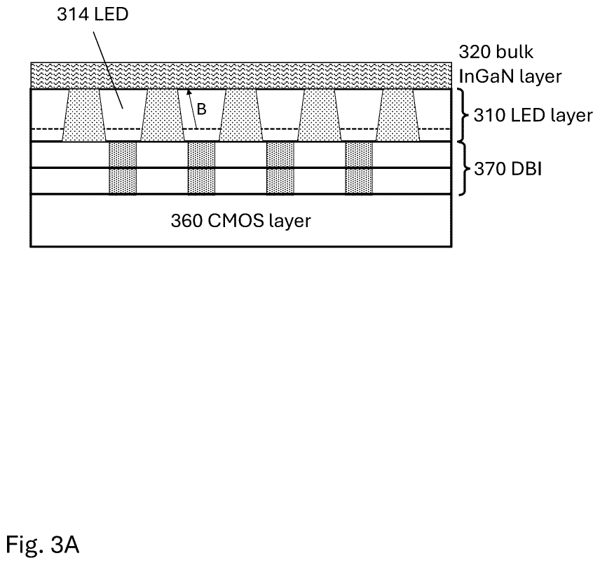

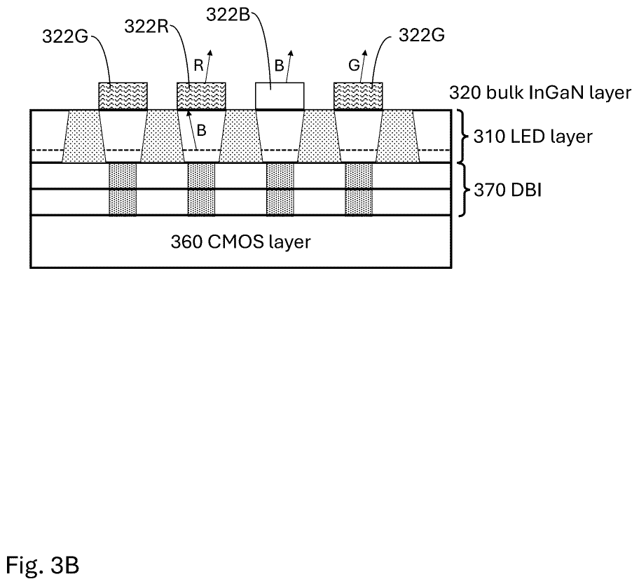

FIG. 3A shows a micro-LED array with a continuous bulk layer 320 of InₓGa₁₋ₓN. This structure includes a CMOS layer 360 attached to an LED layer 310. In this example, the two layers 360, 310 are bonded to each other by direct bond interconnects 370. The CMOS layer 360 includes CMOS driver circuits. The GaN LED layer 310 is patterned into an array of LEDs 314, which are connected to and driven by the driver circuits. In this example, the LEDs are blue LEDs as indicated by the light ray labeled B.

A bulk InₓGa₁₋ₓN color conversion layer 320 is attached to the GaN LED layer 310. The bulk InₓGa₁₋ₓN color conversion layer 320 may be deposited via atomic layer deposition (ALD) or radio frequency (RF) sputtering. Either of these processes may be accomplished at temperatures lower than about 300 degrees Celsius, which is low enough to not harm the CMOS driver layer 360 to which the LED layer 310 is bonded. The InₓGa₁₋ₓN layer 320 may then be patterned using a reactive ion etch with a chlorine-based chemistry such as Cl₂/BCl₂/SiCl₄/Ar.

In particular, the bulk InₓGa₁₋ₓN layer 320 may be patterned into color conversion elements that are aligned with a subset of LEDs in the micro-LED array. Another layer of InₓGa₁₋ₓN, with a different value of x, may then be deposited and patterned into color conversion elements that are aligned with a different subset of LEDs in the array.

FIG. 3B shows an example. The LED layer 310 includes an array of LEDs that produce blue light. The bulk InₓGa₁₋ₓN color conversion layer 320 is patterned into individual color conversion elements 322, which contain different compositions of bulk InₓGa₁₋ₓN (i.e., different values of x). In color conversion element 322R, the value of x is selected so that the element converts the incoming blue light into red light as indicated by the R. Color conversion elements 322G have a value of x that converts the incoming blue light into green light as indicated by the G. Area 322B does not contain bulk InₓGa₁₋ₓN. The incoming blue light remains as blue. In this way, an RGB color light source may be produced.

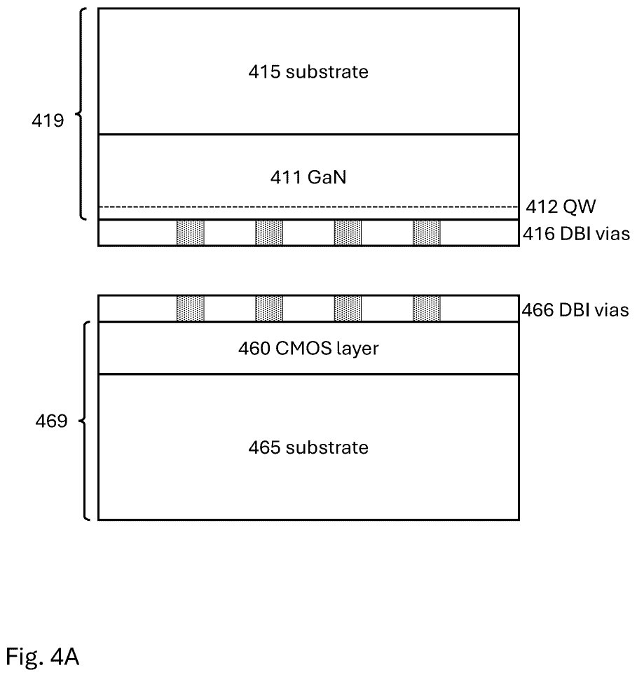

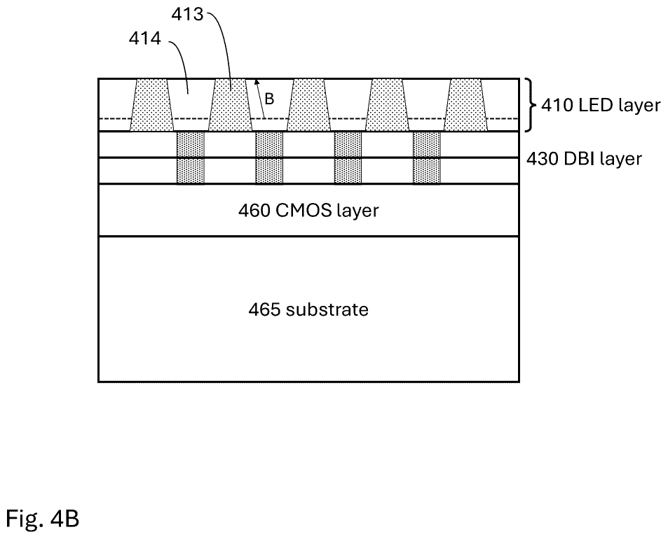

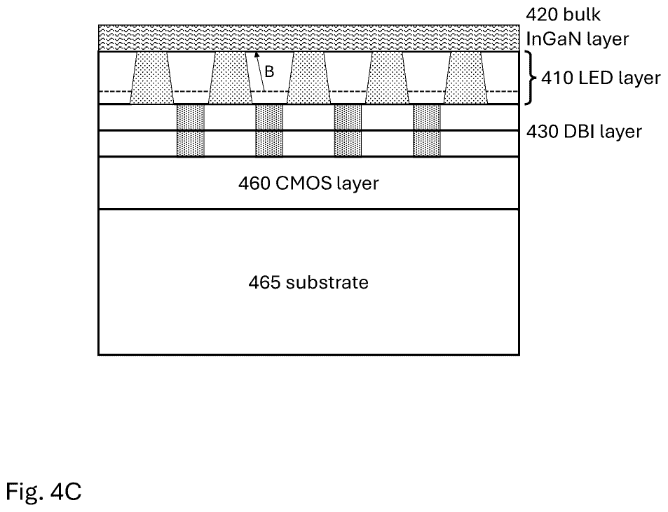

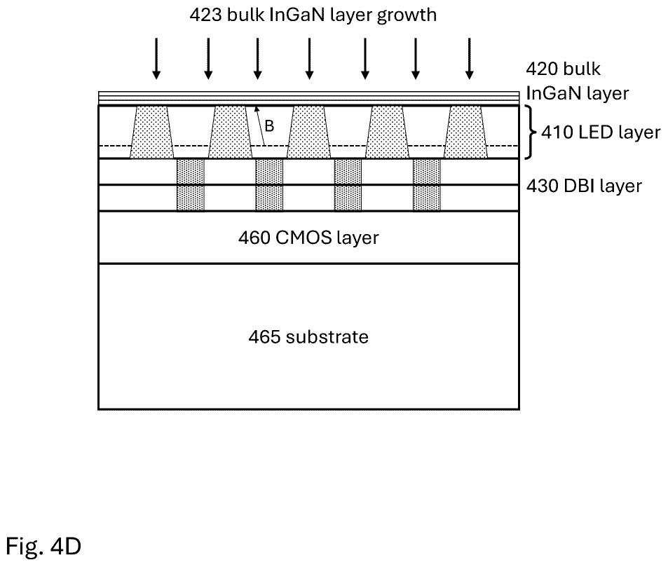

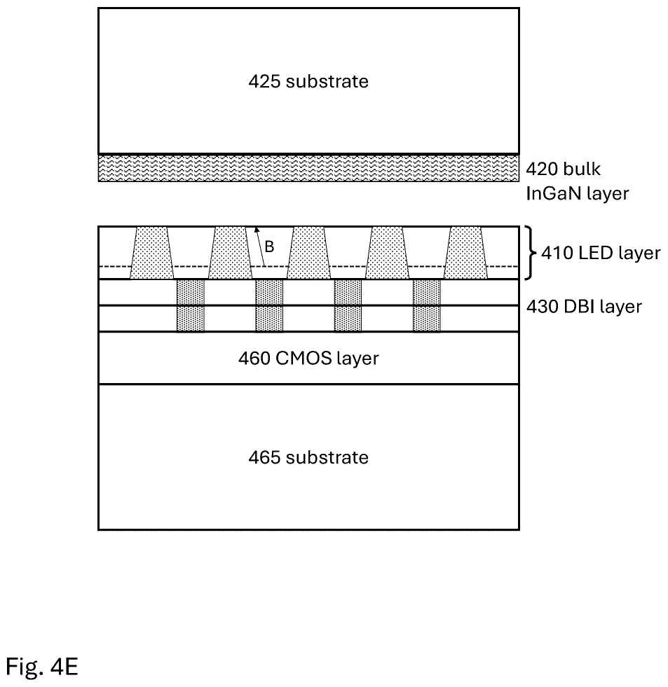

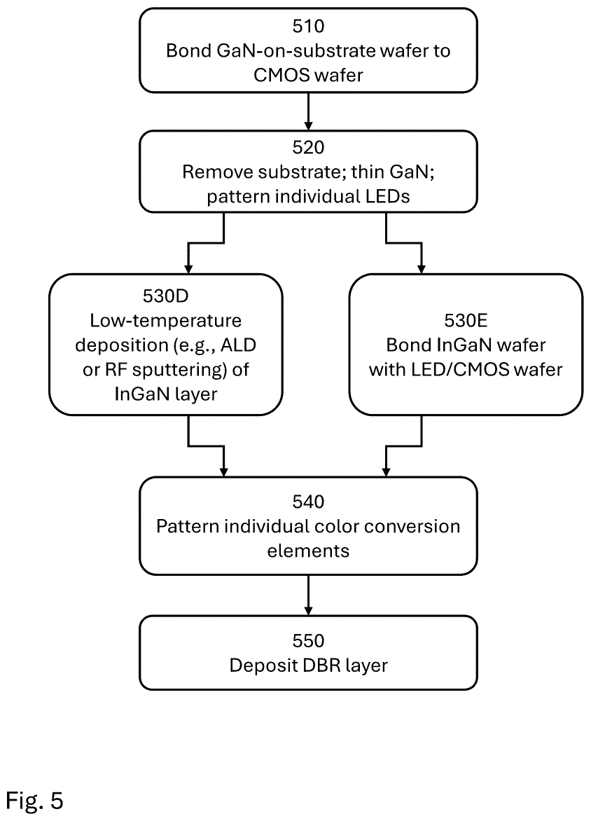

FIGS. 4A-4E show steps for fabricating such a device. FIG. 5 is a corresponding flow diagram.

FIG. 4A shows a CMOS wafer 469 and GaN-on-substrate wafer 419 which are attached by direct bond interconnects (DBI), also known as hybrid bonding (step 510 in FIG. 5). The CMOS wafer 469 includes a CMOS layer 460 which includes the CMOS driver circuits. The circuits are fabricated on a substrate 465, which typically is silicon.

The GaN-on-substrate wafer 419 also includes a substrate 415, which may be silicon, sapphire or another suitable substrate. A few (e.g. 3-7) microns of GaN 411 is epitaxially grown on the substrate 415. The GaN 411 is grown on top of the substrate 415 despite being illustrated farther down the page than the substrate in FIG. 4A. The crystal quality of the GaN improves after the first few microns. Once the quality of the GaN is acceptable, GaN quantum wells 412 are grown to form the light emitting layer of the LEDs. About one micron of GaN is grown on top of the quantum wells.

Hybrid bonding, or DBI, is a process that bonds two wafers together structurally and simultaneously creates electrical interconnects between them. The GaN side of the GaN-on-substrate wafer 419 is the surface bonded to the CMOS wafer 469. A DBI layer 416, 466 on each wafer 419, 469 prepares the wafers for bonding to each other. The DBI layers 416, 466 include oxide on slightly recessed copper plugs (vias). The oxides make contact and bond to each other, and the copper plugs expand during annealing and bond to each other.

FIG. 4B shows step 520 of FIG. 5. After bonding, the substrate 415 is removed, for example by laser liftoff or a chemical-mechanical process. The remaining GaN is thinned, leaving an LED layer 410 approximately 2-3 microns thick and well suited for subsequent InₓGa₁₋ₓN deposition. The thinned GaN is then patterned into individual LEDs 414. The shaded trapezoids 413 between LEDs may be filled with Al to provide electrical contacts and optical isolation between LEDs.

FIG. 4C shows the same structure as FIG. 4B, but with a bulk InₓGa₁₋ₓN color conversion layer 420 fabricated on the GaN LED layer 410. FIG. 4C is the same as FIG. 3A and the color conversion layer may be patterned as described with respect to FIG. 3A.

FIGS. 4D and 4E show two different processes for fabricating the bulk InₓGa₁₋ₓN color conversion layer 420 of FIG. 4C. In FIG. 4D (step 530D of FIG. 5), the bulk InGaN layer 420 is grown directly on the GaN LED layer 410. In this approach, high-temperature (e. g. 800 C) InₓGa₁₋ₓN growth may damage the CMOS circuits 460. Accordingly, the InₓGa₁₋ₓN 420 may be created by growing alternate layers of In, Ga and N. For example, to create In_{0.2}Ga_{0.8}N, one could grow atomic monolayers of In, N, Ga, N, Ga, N, Ga, N, Ga, N, In, N, Ga, N, Ga, N, Ga, N, Ga, N, etc., yielding a 0.2:0.8:1 ratio of In:Ga:N. The atomic monolayers may be created by atomic layer deposition or by RF sputtering, both of which are low temperature processes.

In FIG. 4E (step 530E of FIG. 5), the InₓGa₁₋ₓN layer 420 is grown epitaxially on a substrate 425. The InₓGa₁₋ₓN may be deposited directly by adjusting gas mixtures. After growth, a thin oxide layer (not shown) may be formed on the InₓGa₁₋ₓN 420 to prepare it for direct bonding to a similarly prepared GaN LED layer 410. Direct bonding uses a thin oxide on one or both wafers to be bonded. After bonding, the substrate 425 is removed, for example by grinding.

At 540 of FIG. 5, the InₓGa₁₋ₓN layer is patterned to form individual color conversion elements. The patterning may be done by reactive ion etching. Depending on the fabrication process for the bulk InₓGa₁₋ₓN layer 420, it may also be patterned before attaching to the LED layer. The fabrication and patterning may be repeated for different values of x to create different color conversion elements.

At 550, a DBR layer may be deposited over the LEDs or over certain LEDs. The DBR may reflect red or green depending upon the desired pixel color. The DBR makes the LEDs into resonant cavity LEDs, which improves color conversion efficiency and narrows the radiation pattern in the desired, forward direction.

This process may be incorporated into full-color micro-LED source manufacturing. Bulk InₓGa₁₋ₓN has a high density of states compared to quantum dots. This leads to high optical absorption per unit path length, and given aspect ratio constraints for color conversion elements, allows pixel sizes smaller than about two microns in width.

Although the detailed description contains many specifics, these should not be construed as limiting the scope of the invention but merely as illustrating different examples. It should be appreciated that the scope of the disclosure includes other embodiments not discussed in detail above. Various other modifications, changes and variations which will be apparent to those skilled in the art may be made in the arrangement, operation and details of the method and apparatus disclosed herein without departing from the spirit and scope as defined in the appended claims. Therefore, the scope of the invention should be determined by the appended claims and their legal equivalents.

What is claimed is:

1. An LED source comprising:
a CMOS layer that includes CMOS driver circuits;
a GaN LED layer attached to the CMOS layer, the GaN LED layer patterned into an array of LEDs connected to and driven by the driver circuits; and
a bulk InₓGa₁₋ₓN color conversion layer attached to the GaN LED layer, the bulk InₓGa₁₋ₓN color conversion layer patterned into color conversion elements aligned with corresponding LEDs to convert light from the LEDs to a different wavelength.

2. The LED source of claim 1 wherein the color conversion elements have a height/width aspect ratio less than one.

3. The LED source of claim 1 wherein the LEDs have a width of not more than two microns.

4. The LED source of claim 1 further comprising: a distributed Bragg reflector layer, wherein bulk InₓGa₁₋ₓN color conversion layer is positioned between the distributed Bragg reflector layer and the GaN LED layer.

5. The LED source of claim 1 wherein the LEDs in the array are organized into individually addressable pixels.

6. The LED source of claim 1 wherein the LEDs in the array are organized into color pixels for a color display.

7. The LED source of claim 6 wherein the bulk InₓGa₁₋ₓN color conversion layer includes color conversion elements with at least two different values of x, which convert light from the LEDs to at least two different wavelengths.

8. The LED source of claim 6 wherein the LEDs produce blue light, and the color conversion elements convert the blue light into red light and into green light.

9. A light source comprising:
a die containing a plurality of source elements that produce light; and
bulk InₓGa₁₋ₓN color conversion elements supported by the die and positioned to receive the light from the source elements and convert the received light to a different wavelength.

10. The light source of claim 9 wherein the color conversion elements have a height/width aspect ratio less than one.

11. The light source of claim 9 wherein the color conversion elements have at least two different values of x, which convert light from the source elements to at least two different wavelengths.

12. The light source of claim 9 wherein the color conversion elements comprise a continuous layer of bulk InₓGa₁₋ₓN.

13. A process for making an LED source comprising:
fabricating a GaN LED layer patterned into an array of LEDs; and
fabricating a bulk InₓGa₁₋ₓN color conversion layer on the GaN LED layer, the bulk InₓGa₁₋ₓN color conversion layer patterned into color conversion elements aligned with corresponding LEDs to convert light from the LEDs to a different wavelength.

14. The process of claim 13 wherein fabricating the bulk InₓGa₁₋ₓN color conversion layer comprises:
in a low-temperature process, alternately depositing layers of In, Ga and N to produce the bulk InₓGa₁₋ₓN color conversion layer on the GaN LED layer.

15. The process of claim 14 wherein the low-temperature process is atomic layer deposition (ALD) or radio frequency (RF) sputtering.

16. The process of claim 14 wherein fabricating the bulk InₓGa₁₋ₓN color conversion layer further comprises:
by a reactive ion etch, patterning the bulk InₓGa₁₋ₓN color conversion layer into color conversion elements aligned with the corresponding LEDs.

17. The process of claim 13 wherein fabricating the bulk InₓGa₁₋ₓN color conversion layer comprises:
in a first low-temperature process, depositing alternating layers of InN and GaN to produce a first portion of the bulk InₓGa₁₋ₓN color conversion layer on the GaN LED layer with a first value for x; and
in a second low-temperature process, depositing alternating layers of InN and GaN to produce a second portion of the bulk InₓGa₁₋ₓN color conversion layer on the GaN LED layer with a second different value for x.

18. The process of claim 13 wherein fabricating the bulk InₓGa₁₋ₓN color conversion layer comprises:
growing the bulk InₓGa₁₋ₓN color conversion layer on a substrate;
bonding the bulk InₓGa₁₋ₓN color conversion layer to the GaN LED layer; and
removing the substrate.

19. The process of claim 13 wherein fabricating the GaN LED layer comprises:
bonding a GaN-on-substrate wafer to a CMOS wafer that includes CMOS driver circuits, the GaN-on-substrate wafer comprising a GaN layer supported by a substrate;
removing the substrate from the GaN-on-substrate wafer, and thinning the remaining GaN layer; and
patterning the thinned GaN layer into the array of LEDs.

20. The process of claim 13 wherein the LEDs have a width of not more than two microns, and the color conversion elements have a height/width aspect ratio less than one.
